(19) United States
(12) Patent Application Publication
(10) Pub. No.: US 2026/0316096 A1
(43) Pub. Date: Oct. 15, 2026

(54) WATER OUTLET SWITCHING STRUCTURE AND A WATER OUTLET DEVICE

(71) Applicant: Xiamen Solex High-Tech Industries Co., Ltd., Xiamen (CN)

(72) Inventors: Daqiang Zhang, Xiamen (CN); Xiaolong Lin, Xiamen (CN); Fengde Lin, Xiamen (CN)

(21) Appl. No.: 19/640,524

(22) Filed: Apr. 7, 2026

(30) Foreign Application Priority Data
Apr. 10, 2025 (CN) 202510449716.8

(51) Int. Cl. B05B 1/16; E03C 1/04

(52) U.S. Cl. CPC B05B 1/1636; E03C 1/0408

(57) ABSTRACT

A water outlet switching structure includes an operating member and a linkage member. The operating member is configured to drive the linkage member to move, and the linkage member includes a first direction-changing surface and a holding surface. When the linkage member moves to enable the first direction-changing surface to cooperate with a swinging member, the first direction-changing surface converts the movement of the linkage member into a swing of the swinging member. The swinging member is configured to cooperate with a switching member. When the linkage member moves to enable the holding surface to cooperate with one end of the swinging member, the operating member is configured to drive the linkage member to move relative to a second nozzle to change a shape of a water outlet port of the second nozzle.

### RELATED APPLICATIONS

This application claims priority to Chinese patent application number 202510449716.8, filed on Apr. 10, 2025. Chinese patent application number 202510449716.8 is incorporated herein by reference.

### FIELD OF THE DISCLOSURE

The present disclosure relates to a bathroom product, and more particularly to a water outlet device.

### BACKGROUND OF THE DISCLOSURE

A handheld shower head is a common bathroom fixture, typically used for showering. The handheld shower head can be connected through a water pipe to a faucet or a shower device, and water is sprayed out due to water pressure. Handheld shower heads usually feature adjustable water flow and spray patterns, which can be adjusted according to personal preference and needs. Existing handheld shower heads are all designed to discharge water through multiple water outlet holes at a bottom of the handheld shower head. A water source of the handheld shower head cannot concentrate pressure to spray out from a single water outlet hole, resulting in an inability to thoroughly rinse hard-to-clean areas in a bathroom using the handheld shower head. Therefore, handheld shower heads with a spray gun function have emerged in the existing techniques, adding a spray gun water discharge function in addition to the conventional shower head water discharge. However, the spray pattern of this spray gun function cannot be adjusted, still failing to meet user needs.

### BRIEF SUMMARY OF THE DISCLOSURE

The main technical problem to be solved by the present disclosure is to provide a water outlet switching structure, which can simultaneously achieve water channel switching between different water outlet nozzles and water pattern switching for a same water outlet nozzle.

To solve the aforementioned technical problem, the present disclosure provides a water outlet switching structure, and the water outlet switching structure comprises an operating member, a linkage member, a swinging member, a switching member, a first nozzle, and a second nozzle.

The operating member is configured to drive the linkage member to move, and the linkage member comprises a first direction-changing surface and a holding surface along a direction of movement of the linkage member. When the linkage member moves to enable the first direction-changing surface to cooperate with the swinging member, the first direction-changing surface converts the movement of the linkage member into a swing of the swinging member from a first position to a second position. The swinging member is configured to cooperate with the switching member in a direction-changing manner to convert the swing of the swinging member into movement of the switching member. During the movement of the switching member, the switching member is configured to enable a water inlet channel to be alternatively in communication with a first water outlet channel or a second water outlet channel to discharge water from the first nozzle or the second nozzle.

When the linkage member moves to enable the holding surface to cooperate with a first end of the swinging member, the holding surface maintains the swinging member in the second position, the water inlet channel is in communication with the second water outlet channel, the second nozzle discharges the water, and the operating member is configured to drive the linkage member to move relative to the second nozzle to change a shape of a water outlet port of the second nozzle.

In a preferred embodiment, the swinging member is a swing rod. The first end of the swinging member abuts the linkage member, and a second end of the swinging member abuts the switching member.

In a preferred embodiment, the switching member comprises a water divider, a switching shaft, and a sealing member arranged on the switching shaft, and the water divider comprises the water inlet channel, the first water outlet channel, and the second water outlet channel. The switching shaft is located at junctions at which the water inlet channel is in communication with the first water outlet channel and the second water outlet channel. During the movement of the switching member, the switching member alternatively closes the junction between the water inlet channel and the first water outlet channel or the junction between the water inlet channel and the second water outlet channel through the sealing member.

In a preferred embodiment, the switching shaft abuts the water divider through a return spring. When the switching shaft moves to enable the second water outlet channel to be in communication with the water inlet channel, the return spring accumulates an elastic return force.

In a preferred embodiment, the linkage member further comprises a second direction-changing surface. When the linkage member moves to enable the holding surface to cooperate with the first end of the swinging member, the second direction-changing surface is operatively coupled to the second nozzle to change the shape of the water outlet port of the second nozzle.

In a preferred embodiment, the second nozzle further comprises a direction-changing cooperating member, and the second direction-changing surface is configured to move relative to the second nozzle to convert movement of the second direction-changing surface along an axial direction of the linkage member into movement of the direction-changing cooperating member along a radial direction of the second nozzle.

In a preferred embodiment, the second direction-changing surface is an inclined surface.

In a preferred embodiment, the second nozzle further comprises a nozzle body, and the direction-changing cooperating member comprises two clamping plates arranged on two sides of the nozzle body. The two clamping plates are connected by an elastic member to form a cavity, and a water outlet end of the nozzle body is arranged within the cavity. The water outlet end of the nozzle body is operatively coupled to the two clamping plates through a pin shaft.

In a preferred embodiment, the linkage member is partially arranged between the two clamping plates. While the linkage member moves relative to the second nozzle, the second direction-changing surface abuts and cooperates with the two clamping plates to be configured to drive the two clamping plates to splay away from each other.

In a preferred embodiment, the nozzle body has a linear water outlet port when the two clamping plates are in an initial position.

In a preferred embodiment, the operating member configured to drive the linkage member to move along an axial direction of the linkage member.

In a preferred embodiment, the first direction-changing surface is an inclined surface, and the holding surface is a flat, straight surface connected to an end of the inclined surface and extends along an axial direction of the linkage member.

In a preferred embodiment, the operating member is a push button.

The present disclosure further provides a water outlet switching structure, and the water outlet switching structure comprises an operating member, a linkage member, and a nozzle.

The linkage member comprises a direction-changing surface, and the direction-changing surface is configured to be operatively coupled to the nozzle, so that the operating member is configured to drive the linkage member to move relative to the nozzle to change a shape of a water outlet port of the nozzle.

In a preferred embodiment, the nozzle further comprises a direction-changing cooperating member, and the direction-changing surface is configured to move relative to the nozzle to convert movement of the direction-changing surface along an axial direction of the linkage member into movement of the direction-changing cooperating member along a radial direction of the nozzle.

In a preferred embodiment, the direction-changing surface is an inclined surface.

In a preferred embodiment, the nozzle further comprises a nozzle body, and the direction-changing cooperating member is two clamping plates arranged on two sides of the nozzle body. The two clamping plates are connected by an elastic member to form a cavity, and a water outlet end of the nozzle body is arranged within the cavity. The water outlet end of the nozzle body is operatively coupled to the two clamping plates through a pin shaft.

In a preferred embodiment, the linkage member is partially arranged between the two clamping plates. While the linkage member moves relative to the nozzle, the direction-changing surface abuts and cooperates with the two clamping plates to be configured to drive the two clamping plates to splay away from each other.

In a preferred embodiment, the nozzle body has a linear water outlet port when the two clamping plates are in an initial position, and a side of the nozzle body has a clearance notch in communication with the linear water outlet port.

In a preferred embodiment, the operating member is configured to drive the linkage member to move along an axial direction of the linkage member.

The present disclosure further provides a water outlet device, and the water outlet device is assembled with the water outlet switching structure and comprises a body and a water outlet cover. The body comprises a head portion and a handle. The first nozzle is arranged on the water outlet cover, and the second nozzle is arranged at an end of the head portion away from the handle.

The present disclosure further provides a water outlet device, and the water outlet device is assembled with the water outlet switching structure and comprises a body and a water outlet cover. The body comprises a head portion and a handle, and the nozzle is arranged at an end of the head portion away from the handle.

Compared with the existing techniques, the technical solution has the following advantages.

The present disclosure provides a water outlet switching structure, which, in addition to switching between the first nozzle and the second nozzle for water discharging, can also change the shape of the second nozzle to change its water outlet pattern.

### BRIEF DESCRIPTION OF THE DRAWINGS

FIG. 1 is a perspective view of a water outlet device in a preferred embodiment of the present disclosure.

FIG. 2 is an exploded view of the water outlet device in the preferred embodiment of the present disclosure.

FIG. 3 is a perspective view of an internal structure of the water outlet device when a first nozzle is discharging water in the preferred embodiment of the present disclosure.

FIG. 4 is another perspective view of the internal structure of the water outlet device when the first nozzle is discharging water in the preferred embodiment of the present disclosure.

FIG. 5 is a top view of the water outlet device when the first nozzle is discharging water in the preferred embodiment of the present disclosure.

FIG. 6 is a cross-sectional view along line A-A in FIG. 5.

FIG. 7 is a cross-sectional view along line B-B in FIG. 6.

FIG. 8 is a schematic diagram showing a position of a second nozzle and a linkage member in the water outlet device when the first nozzle is discharging water in the preferred embodiment of the present disclosure.

FIG. 9 is a schematic diagram showing a shape of a water outlet port of the second nozzle when the first nozzle is discharging water in the preferred embodiment of the present disclosure.

FIG. 10 is a perspective view of the internal structure of the water outlet device when the second nozzle is discharging water in the preferred embodiment of the present disclosure.

FIG. 11 is another perspective view of the internal structure of the water outlet device when the second nozzle is discharging water in the preferred embodiment of the present disclosure.

FIG. 12 is a top view of the water outlet device when the second nozzle is discharging water in the preferred embodiment of the present disclosure.

FIG. 13 is a cross-sectional view along line A-A in FIG. 12.

FIG. 14 is a cross-sectional view along line B-B in FIG. 13.

FIG. 15 is a schematic diagram showing the position of the second nozzle and the linkage member when the second nozzle is discharging water in the preferred embodiment of the present disclosure.

FIG. 16 is a schematic diagram showing the shape of the water outlet port of the second nozzle when the second nozzle is discharging water in the preferred embodiment of the present disclosure.

FIG. 17 is a perspective view of the internal structure of the water outlet device when the second nozzle is splayed in the preferred embodiment of the present disclosure.

FIG. 18 is another perspective view of the internal structure of the water outlet device when the second nozzle is splayed in the preferred embodiment of the present disclosure.

FIG. 19 is a top view of the water outlet device when the second nozzle is splayed in the preferred embodiment of the present disclosure.

FIG. 20 is a cross-sectional view along line A-A in FIG. 19.

FIG. 21 is a cross-sectional view along line B-B in FIG. 20.

FIG. 22 is a schematic diagram showing the position of the second nozzle and the linkage member when the second nozzle is splayed in the water outlet device in the preferred embodiment of the present disclosure.

FIG. 23 is a schematic diagram showing the shape of the water outlet port of the second water outlet when the second nozzle is splayed in the water outlet device in the preferred embodiment of the present disclosure.

FIG. 24 is a perspective view of the internal structure of the water outlet device when the second nozzle is splayed to a maximum extent in the preferred embodiment of the present disclosure.

FIG. 25 is another perspective view of the internal structure of the water outlet device when the second nozzle is splayed to the maximum extent in the preferred embodiment of the present disclosure.

FIG. 26 is a top view of the water outlet device when the second nozzle is splayed to the maximum extent in the preferred embodiment of the present disclosure.

FIG. 27 is a cross-sectional view along line A-A in FIG. 26.

FIG. 28 is a cross-sectional view along line B-B in FIG. 27.

FIG. 29 is a schematic diagram showing the position of the second nozzle and the linkage member when the second nozzle is splayed to the maximum extent in the water outlet device in the preferred embodiment of the present disclosure.

FIG. 30 is a schematic diagram showing the shape of the water outlet port of the second nozzle when the second nozzle is splayed to the maximum extent in the preferred embodiment of the present disclosure.

FIG. 31 is an exploded view of the second nozzle in the preferred embodiment of the present disclosure.

### DETAILED DESCRIPTION OF THE EMBODIMENTS

To make the technical solutions and features of the present disclosure clearer, the present disclosure is further described in detail below with reference to the accompanying drawings and specific examples. It should be understood that these examples are only used to illustrate the present disclosure and not to limit the scope of the present disclosure. After reading the present disclosure, various equivalent modifications made by those skilled in the art to the present disclosure fall within the scope defined by the appended claims of this application.

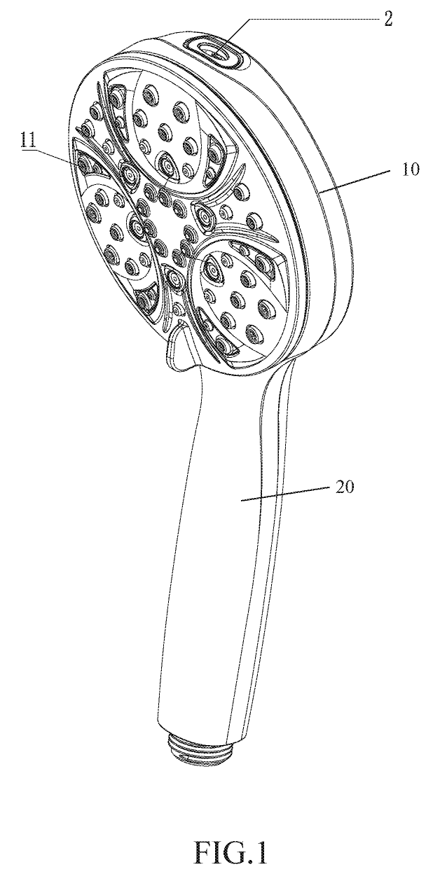

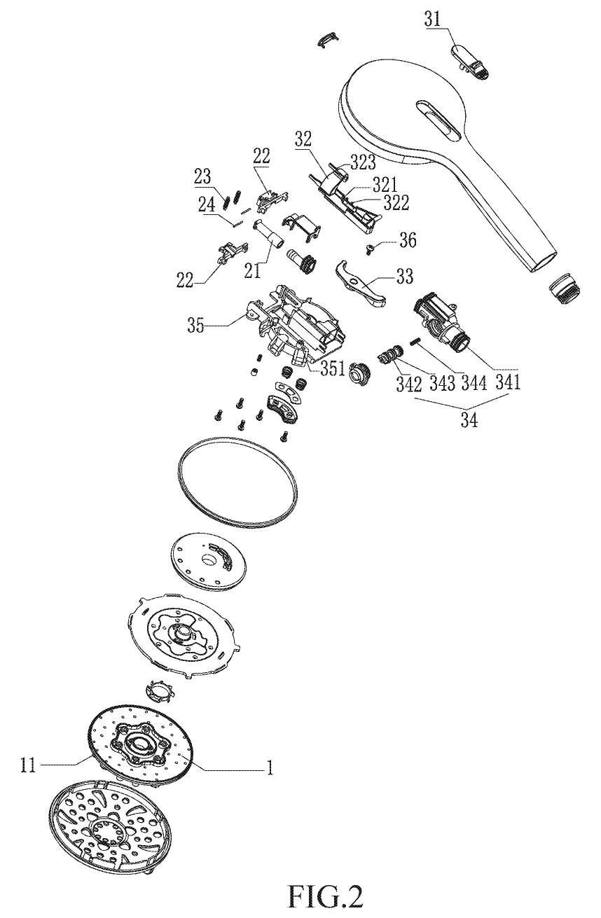

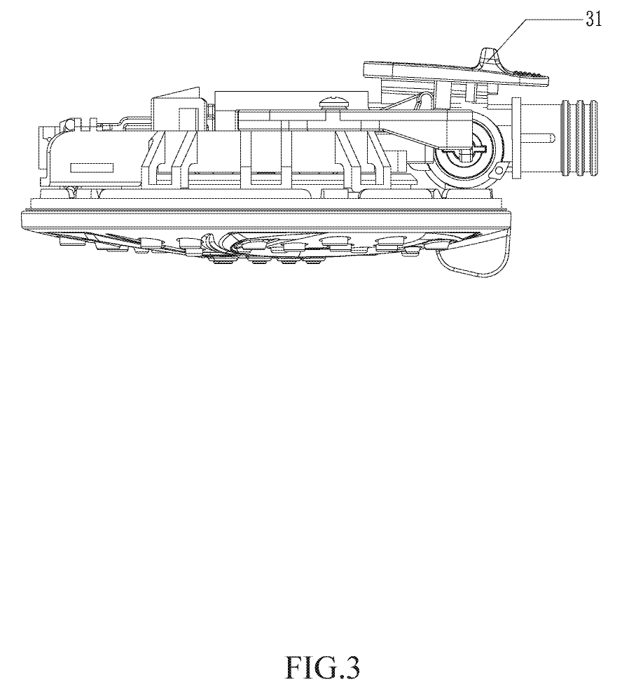

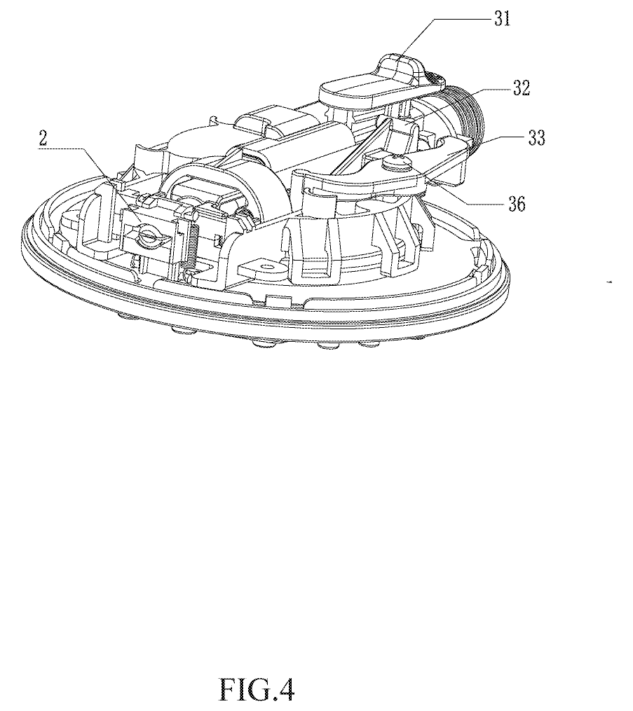

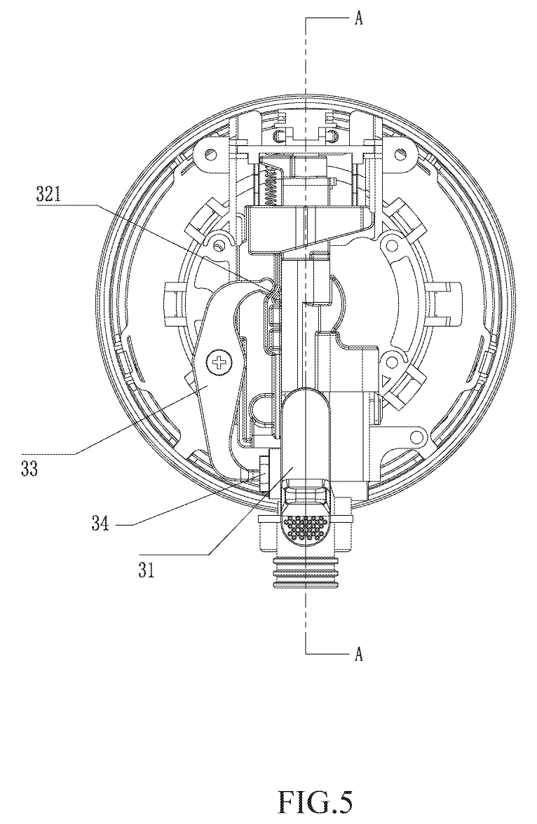

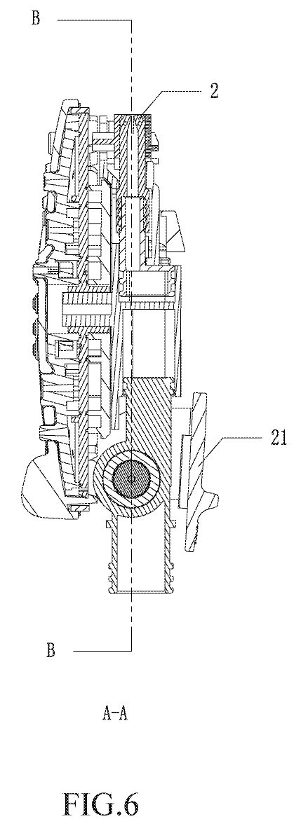

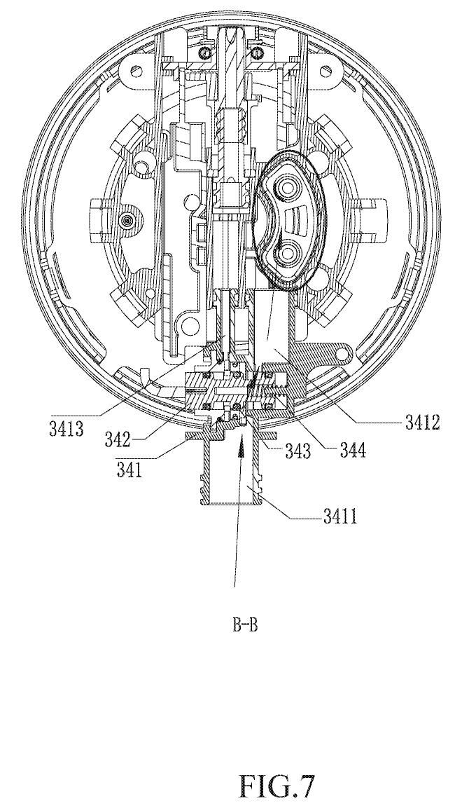

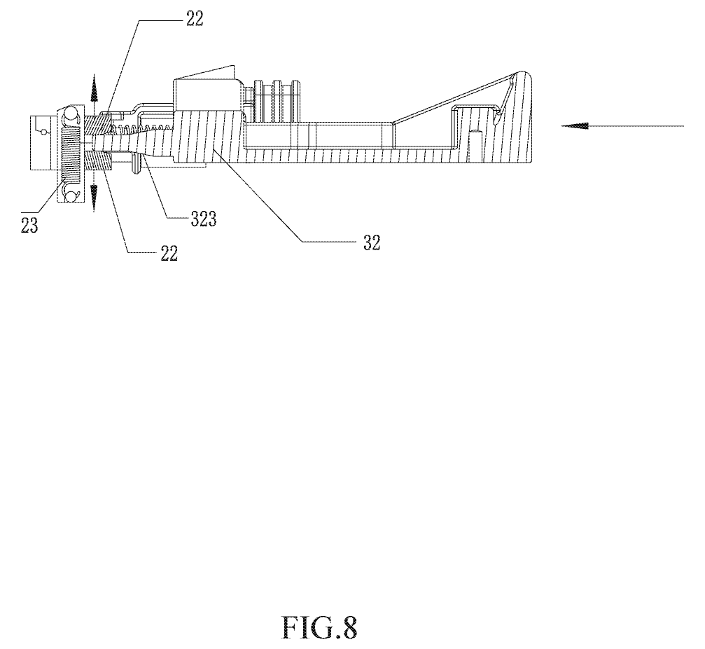

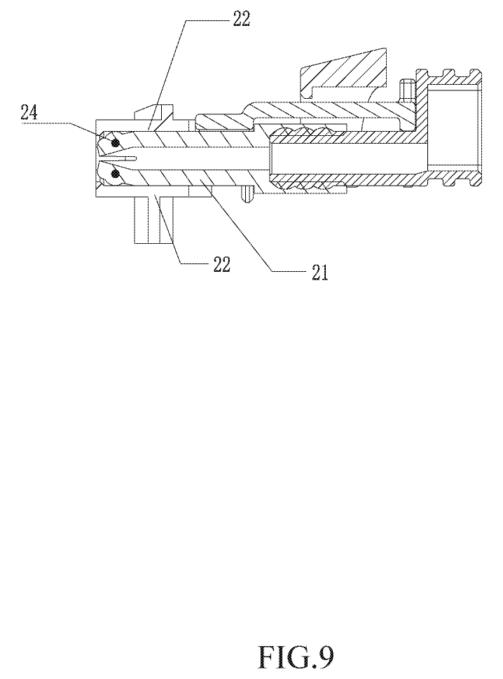

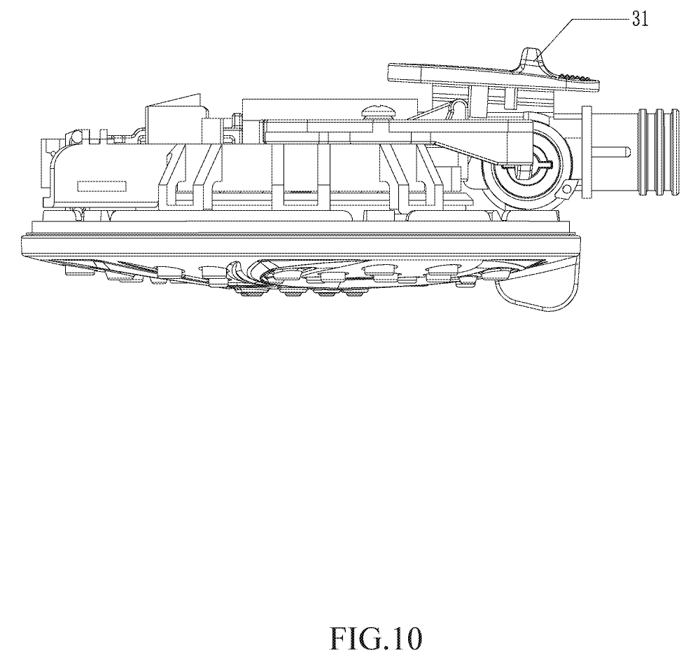

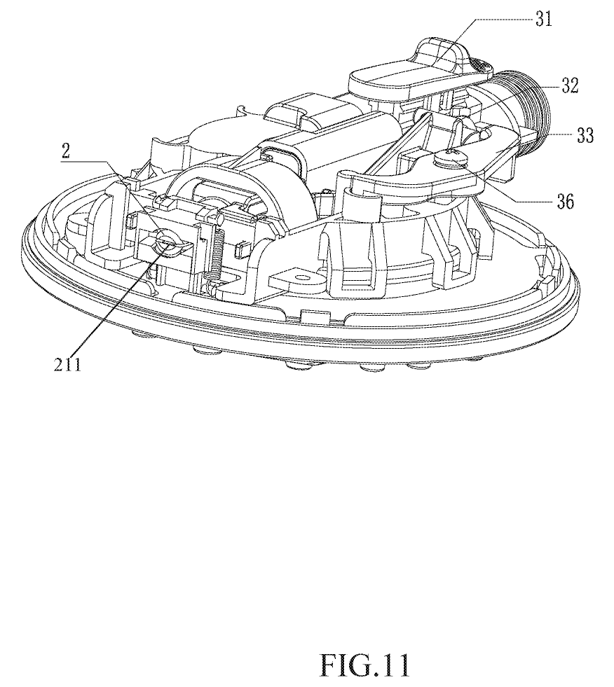

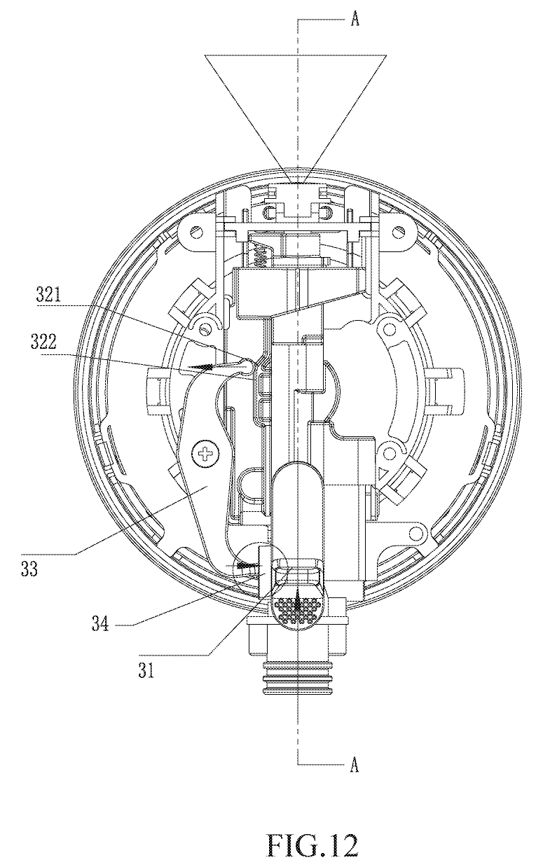

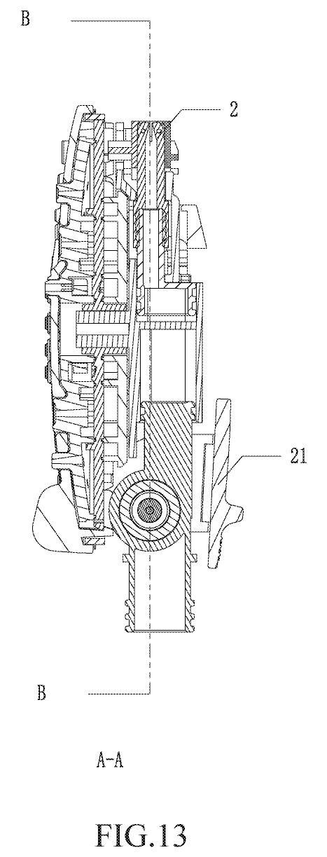

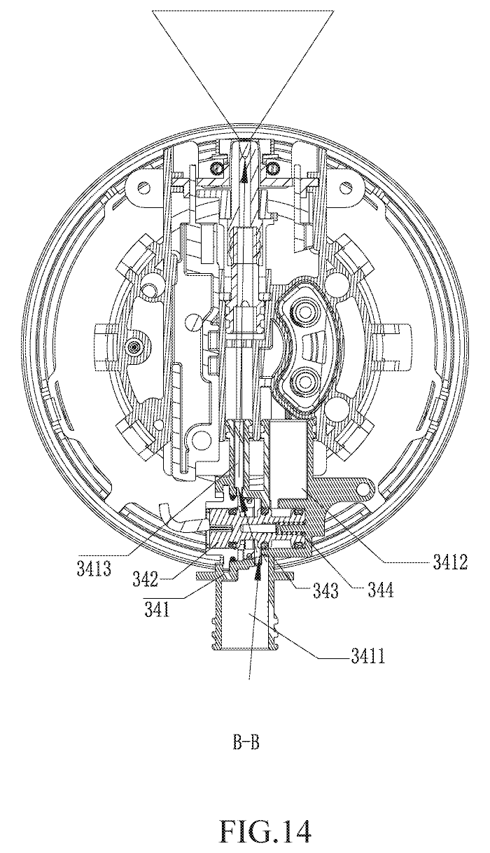

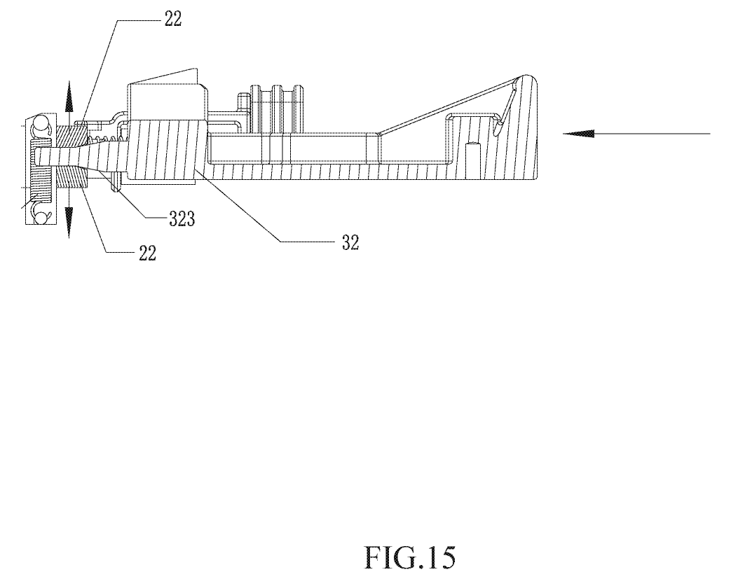

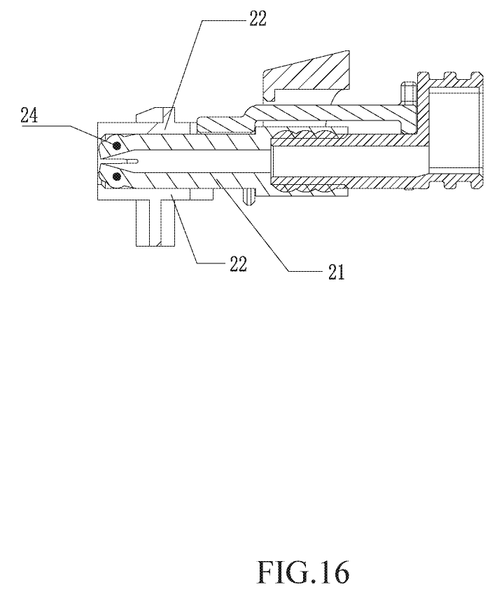

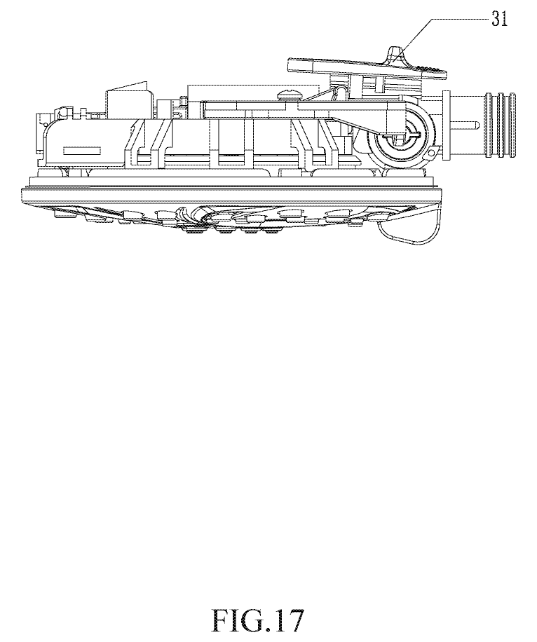

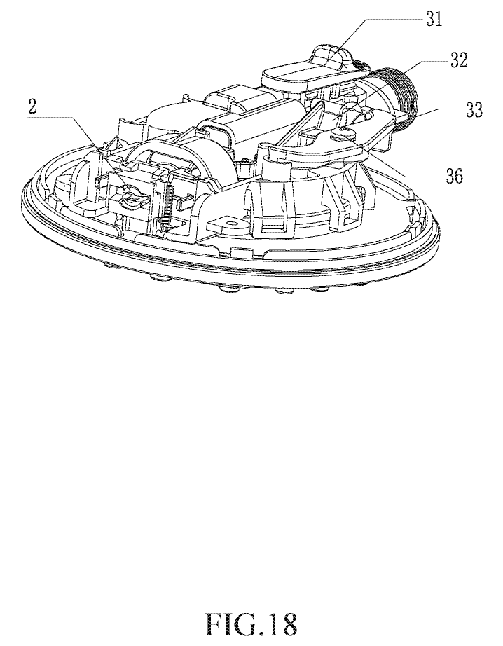

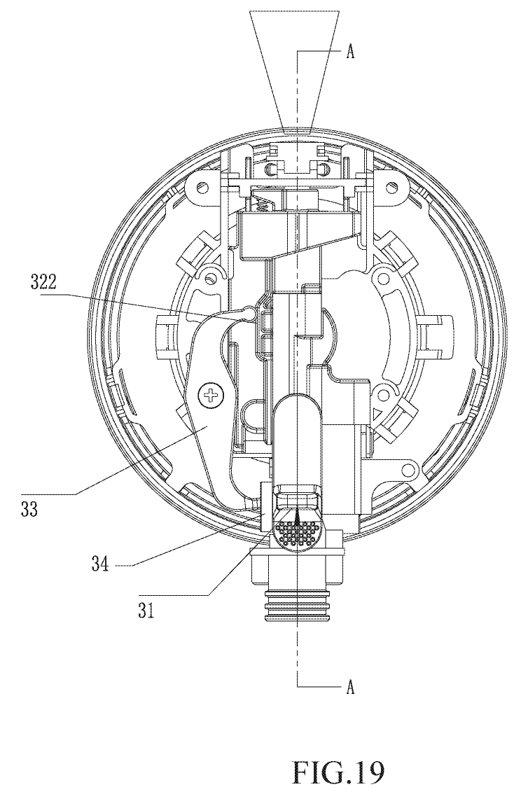

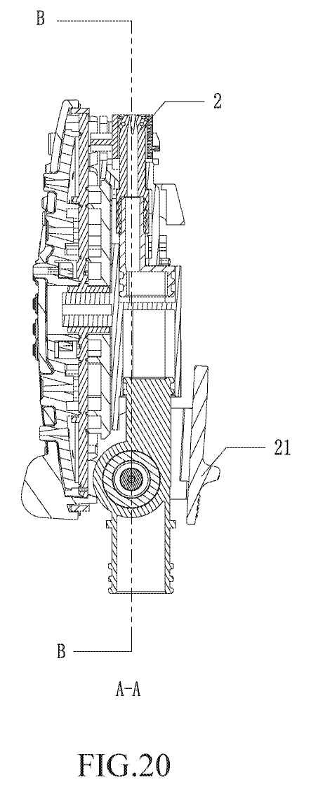

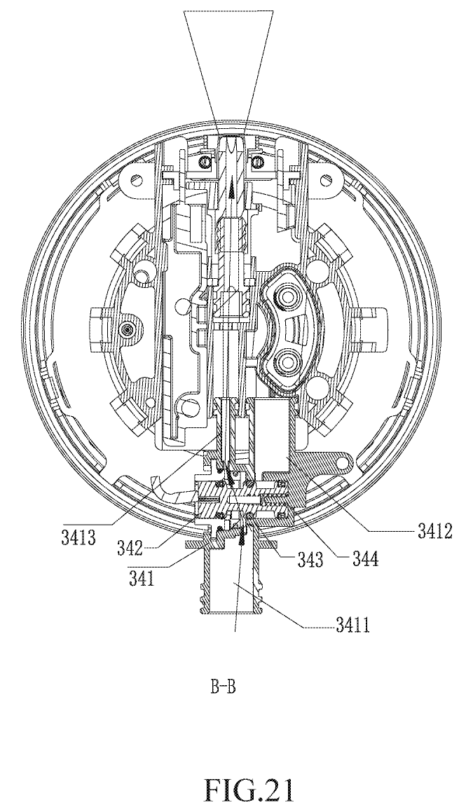

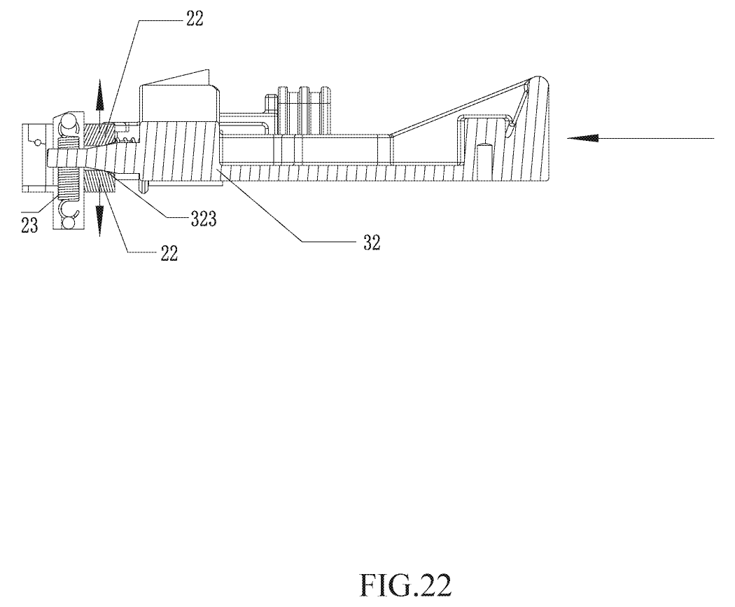

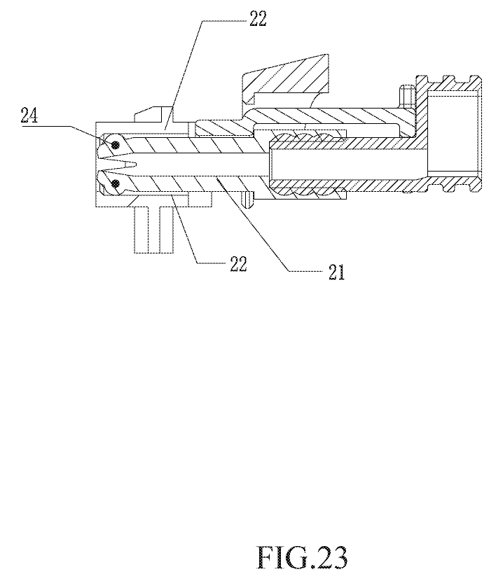

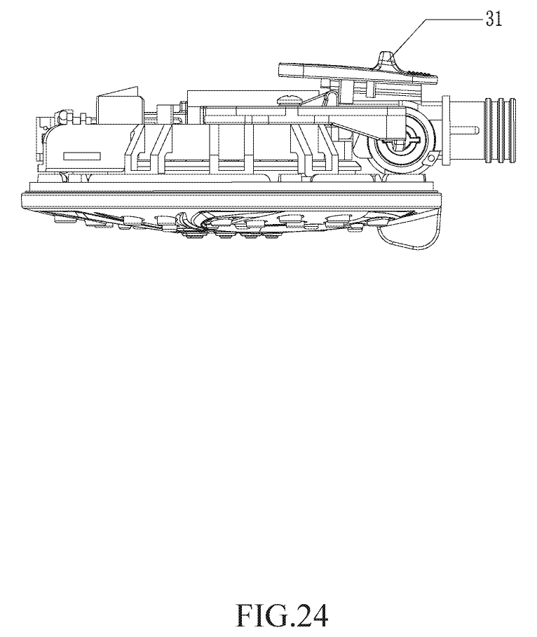

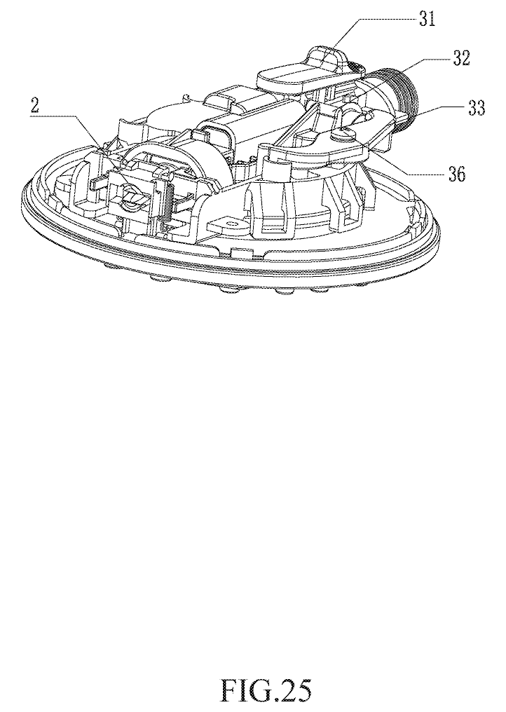

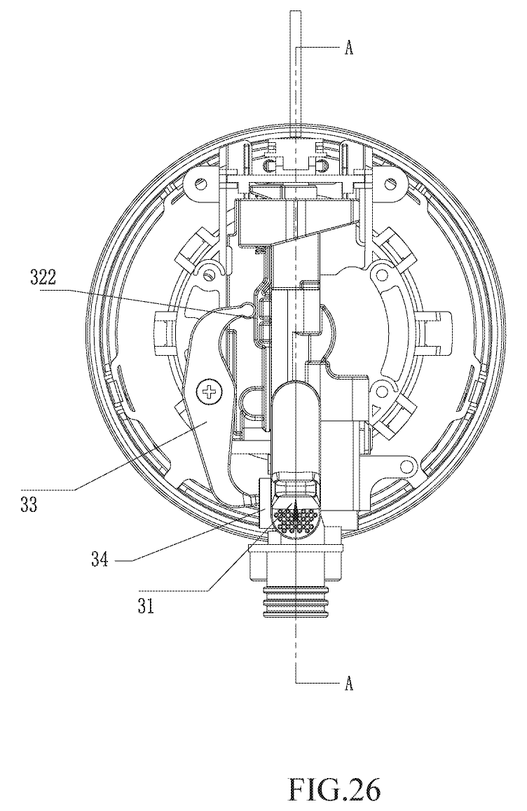

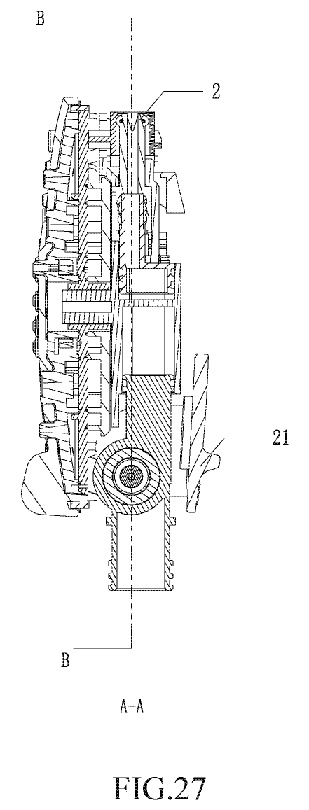

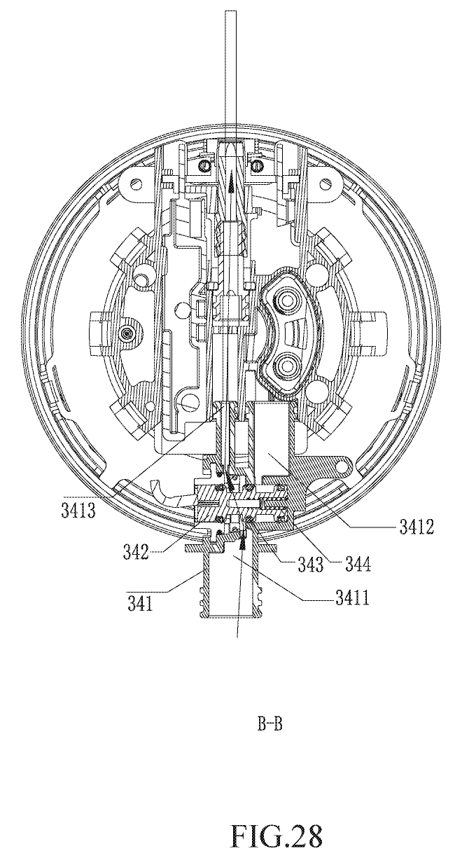

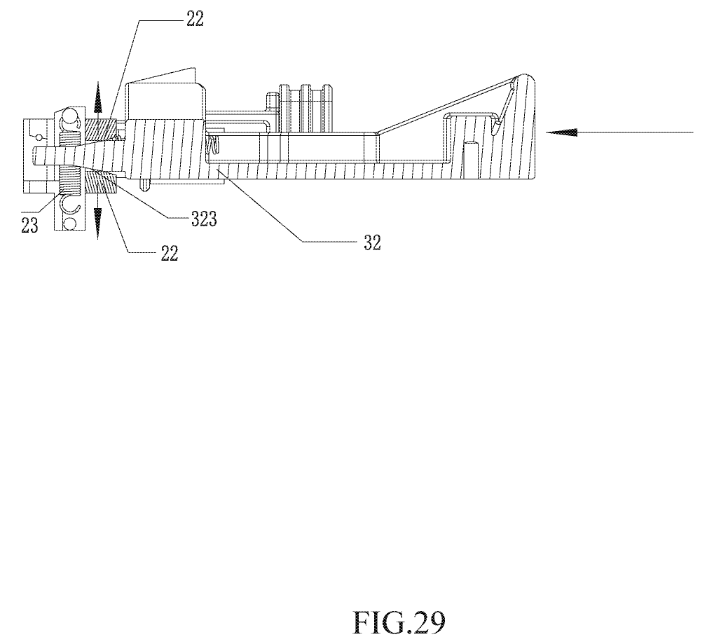

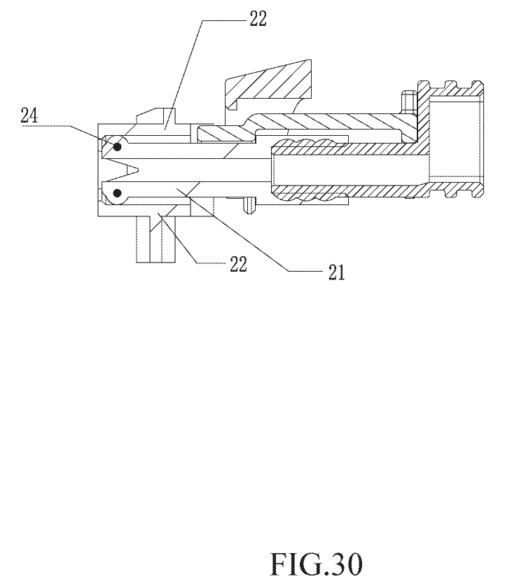

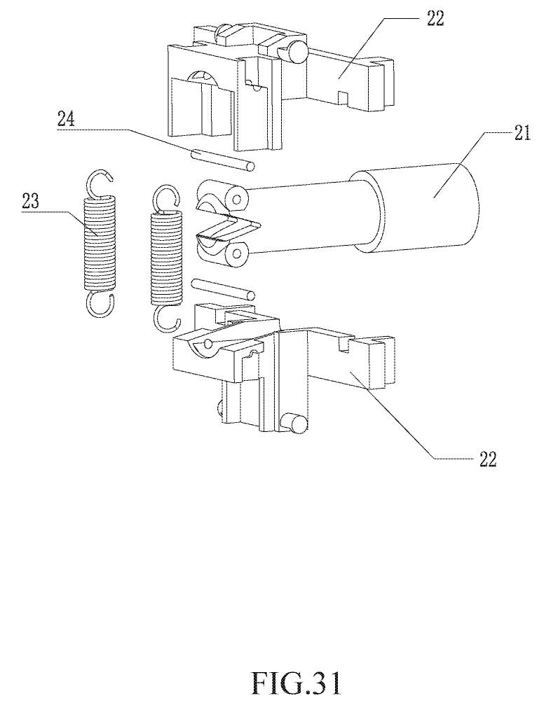

Referring to FIGS. 1-31, this embodiment provides a water outlet device according to the present disclosure, using a handheld shower head as an example in this embodiment. The handheld shower head comprises a head portion 10 and a handle 20. The handheld shower head comprises a conventional first nozzle 11 on a water outlet cover 1, as well as a second nozzle 2 forming a spray gun function located at an end of the head portion 10 of the handheld shower head away from the handle 20, thereby forming a handheld shower head with the spray gun function. Since the handheld shower head has two different water outlet functions, it is necessary to provide a water outlet switching structure to allow users to conveniently choose different water outlet nozzles (i.e., the first nozzle 11 and the second nozzle 2) to discharge water. In addition to enabling switching the water to be discharged from the first nozzle 11 or the second nozzle 2, the water outlet switching structure in this embodiment is further configured to change a shape of the second nozzle 2, thereby changing a water discharge pattern of the second nozzle 2. For example, a wide-range but low-impact linear spray gun water, a narrow-range but high-impact linear spray gun water, or a cylindrical spray gun water with a smallest range but strongest impact. That is, a water coverage area and a water outlet force of the second nozzle 2 can be changed.

To achieve a water channel switching function and a water pattern switching function, the water outlet switching structure in this embodiment comprises an operating member 31, a linkage member 32, a swinging member 33, and a switching member 34.

The operating member 31 is configured to drive the linkage member 32 to move along an axial direction of the linkage member 32. The linkage member 32 comprises a first direction-changing surface 321 and a holding surface 322 successively arranged along a direction of movement of the linkage member 32. Thus, during the movement of the linkage member 32 driven by the operating member 31, the first direction-changing surface 321 or the holding surface 322 can alternatively cooperate with the swinging member 33. When the linkage member 32 is moved to a position at which the first direction-changing surface 321 cooperates with the swinging member 33, the first direction-changing surface 321 converts the movement of the linkage member 32 in the axial direction of the linkage member 32 into a swing of the swinging member 33 from a first position to a second position. Furthermore, the swinging member 33 also cooperates with the switching member 34 in a direction-changing manner to convert the swing of the swinging member 33 into movement of the switching member 34. This enables the operating member 31 to drive the linkage member 32 to move, the linkage member 32 to drive the swinging member 33 to swing, and the swinging member 33 to then drive the switching member 34 to move, so that the switching member 34 enables a water inlet channel 3411 to be alternatively in communication with a first water outlet channel 3412 or a second water outlet channel 3413, allowing the water to flow out from the first nozzle 11 or the second nozzle 2. This accomplishes the water channel switching function in which the water is switched to flow out from the first nozzle 11 or the second nozzle 2. In this embodiment, when the swinging member 33 is in the first position, the water inlet channel 3411 is in communication with the first water outlet channel 3412, and the water flows out from the first nozzle 11. When the swinging member 33 is in the second position, the water inlet channel 3411 is in communication with the second water outlet channel 3413, and the water flows out from the second nozzle 2.

When the linkage member 32 moves to a position at which the holding surface 322 cooperates with one end of the swinging member 33, the holding surface 322 maintains the swinging member 33 in the second position, which is a state in which the second nozzle 2 discharges the water. At this point, when the operating member 31 continues to drive the linkage member 32 to move, since the swinging member 33 remains in cooperation with the holding surface 322, the swinging member 33 will not swing, and consequently, the switching member 34 will not move. Therefore, the second nozzle 2 remains in a constant water-discharging state. During the movement of the linkage member 32, the linkage member 32 moves relative to the second nozzle 2 until the linkage member 32 abuts the second nozzle 2. When the linkage member 32 abuts the second nozzle 2, the linkage member 32 causes the second nozzle 2 to deform, thereby changing the water coverage area of the second nozzle 2. Since a flow rate is constant, a change in the water coverage area results in a corresponding change in water flow intensity. Thus, this achieves a change in the water discharge pattern. Furthermore, it can be seen that the operating member 31 always moves in a same direction. Initially, the water discharging from the first nozzle 11 being changed to discharging from the second nozzle 2 is achieved. After switching of the water flowing out from the first nozzle 11 to flowing out from the second nozzle 2 is complete, continuing to move the operating member 31 allows for switching the water discharge pattern of the second nozzle 2. The entire operation is very simple and easy to use.

Specifically, in this embodiment, the first direction-changing surface 321 is an inclined surface, and the holding surface 322 is a flat, straight surface connected to an end of the inclined surface and extending along the axial direction of the linkage member 32. The operating member 31 is a push button, located on a back of the handheld shower head, which is a side away from the water outlet cover 1.

In this embodiment, the swinging member 33 is a swing rod. The one end of the swinging member 33 abuts the linkage member 32, and the other end of the swinging member 33 abuts the switching member 34. A middle part of the swing rod is connected through a bolt 36 to a cylinder 351 on a base 35, forming a pivot point for a swing of the swing rod.

To achieve the water channel switching function, the switching member 34 in this embodiment comprises a water divider 341 installed on the base 35, a switching shaft 342, and a sealing member 343 arranged on the switching shaft 342. The water divider 341 comprises the water inlet channel 3411, the first water outlet channel 3412, and a second water outlet channel 3413. The switching shaft 342 is located at junctions at which the water inlet channel 3411 is in communication with the first water outlet channel 3412 and the second water outlet channel 3413. During movement of the switching member 34, the switching member 34 uses the sealing member 343 to alternatively close the junction between the water inlet channel 3411 and the first water outlet channel 3412 or the junction between the water inlet channel 3411 and the second water outlet channel 3413. Specifically, in this embodiment, the second water outlet channel 3413 and the water inlet channel 3411 are arranged front and back along an axial direction of the water divider 341. The first water outlet channel 3412 is located on a side of the second water outlet channel 3413. The switching member 34 is installed inside the water divider 341 along a direction perpendicular to the axial direction of the water divider 341. This allows the switching shaft 342, due to the swing rod, to move in a direction perpendicular to the axial direction of the water divider 341. Consequently, the sealing member 343 closes the junction between the first water outlet channel 3412 and the water inlet channel 3411, while opening the junction between the second water outlet channel 3413 and the water inlet channel 3411, thereby stopping the water from flowing into the first water outlet channel 3412 and allowing the water to flow into the second water outlet channel 3413.

To enable the water to flow into the first water outlet channel 3412 and stop the water flowing into the second water outlet channel 3413, the switching shaft 342 abuts the water divider 341 through a return spring 344. When the switching shaft 342 moves to enable the second water outlet channel 3413 to be in communication with the water inlet channel 3411, the return spring 344 accumulates an elastic return force. Therefore, when the swing rod resets and a force between the swing rod and the switching shaft 342 disappears, the return spring 344 can release the elastic return force, causing the switching shaft 342 to drive the sealing member 343 back to an original position to close the junction between the second water outlet channel 3413 and the water inlet channel 3411, while opening the junction between the first water outlet channel 3412 and the water inlet channel 3411, thereby stopping the water from flowing into the second water outlet channel 3413 and allowing the water to flow into the first water outlet channel 3412.

In this embodiment, the linkage member 32 further comprises a second direction-changing surface 323. When the linkage member 32 moves to a position where the holding surface 322 cooperates with the one end of the swinging member 33, the second direction-changing surface 323 can be drivingly operatively coupled to the second nozzle 2 to change the shape of the second nozzle 2. Specifically, the second nozzle 2 further comprises a direction-changing cooperating member. The second direction-changing surface 323 and the second nozzle 2 are configured to move relative to each other, converting movement of the second direction-changing surface 323 along the axial direction of the linkage member 32 into movement of the direction-changing cooperating member along a radial direction of the second nozzle 2. In other words, during water channel switching, the first direction-changing surface 321 and the swing rod cooperate with each other in a direction-changing interaction. During water pattern switching, the second direction-changing surface 323 abuts the second nozzle 2.

In this embodiment, the second direction-changing surface 323 is also an inclined surface.

To achieve the aforementioned functions, in this embodiment, the second nozzle 2 comprises a nozzle body 21 and two clamping plates 22 arranged on two sides of the nozzle body 21. The two clamping plates 22 serve as the direction-changing cooperating member. The two clamping plates 22 are connected by a tension spring 23 (i.e., an elastic member) to form a cavity. As a simple replacement, the tension spring 23 can also be replaced with other common elastic components in the existing techniques, as long as an elastic restoring force can be accumulated when the two clamping plates 22 are splayed. A water outlet end of the nozzle body 21 is arranged within the cavity and is movably connected to the two clamping plates 22 through a pin shaft 24. The linkage member 32 is partially arranged between the two clamping plates 22. When the second nozzle 2 is in a water outlet state, continuing to drive the linkage member 32 through the operating member 31 will cause the second direction-changing surface 323 to abut the two clamping plates 22, thereby driving the two clamping plates 22 to splay away from each other. Since the two clamping plates 22 and the nozzle body 21 are connected through the pin shaft 24, and the nozzle body 21 has a clearance notch in communication with a linear water outlet port 211. During a process of the two clamping plates 22 splaying, the nozzle body 21 is also pulled outward, causing a length of the linear water outlet port 211 of the nozzle body 21 to shorten and a width of the linear water outlet port 211 of the nozzle body 21 to increase. Thus, the water coverage area changes from an original large linear shape to a small linear shape, thereby reducing a rinsing range of a water spray but increasing an impact force. Subsequently, when continuing to drive the linkage member 32 through the operating member 31, the length of the linear water outlet port 211 is further shortened, and the width of the linear water outlet port 211 is increased, causing the original linear water outlet port 211 to further deform into a quasi-circular water outlet port. The water spray changes from a linear sheet of water to a columnar stream, further increasing the impact force and further reducing the water coverage area. Since the tension spring 23 is stretched and accumulates the elastic restoring force during a splaying process of the two clamping plates 22, when the user operates the push button to reset, the two clamping plates 22 will reset due to the tension spring 23.

It should be noted that in this embodiment, the second direction-changing surface 323 and the two clamping plates 22 cooperate through the inclined surface (i.e., the second direction-changing surface 323), and the two clamping plates 22 comprise inclined surfaces that cooperate with the second direction-changing surface 323. As a simple alternative, the two clamping plates 22 can also be arranged in a scissor-like mechanism. The second direction-changing surface 323 is inserted from one side into the scissor-like mechanism, driving the one side of the scissor-like mechanism to splay, while the other side of the scissor-like mechanism closes and abuts the nozzle body 21, causing the nozzle body 21 to deform. Therefore, the arrangement can vary as long as the second direction-changing surface 323 and the direction-changing cooperating member can achieve converting the movement of the linkage member 32 along the axial direction of the linkage member 32 into the movement of the direction-changing cooperating member along the radial direction of the second nozzle 2. As for whether the direction-changing cooperating member undergoes translation, rotation, or swinging after cooperating with the second direction-changing surface 323, all fall within the scope of simple alternatives in this embodiment. Furthermore, the operating member 31 driving the linkage member 32 to move axially is merely one feasible solution in this embodiment. As a possible alternative, the operating member 31 could also drive the linkage member 32 to rotate. During rotation, the linkage member 32 drives the swinging member 33 to swing through an inclined surface (i.e., the first direction-changing surface 321).

In this embodiment, the linkage member 32 is a push rod. A bottom of the push button comprises a groove, and the push rod has a rib inserted into the groove, thereby achieving linkage between the push button and the push rod.

Additionally, this embodiment takes the water outlet device with two nozzles as an example. Therefore, the water outlet switching structure needs to simultaneously possess functions of switching between the first nozzle 11 or the second nozzle 2 for water output, or changing the water output form of the second nozzle 2. If the water outlet device has only one nozzle, then the water outlet switching structure may only need to possess the function of changing the water output form of the nozzle.

The above description is merely one specific embodiment of the present disclosure. However, the design concept of the present disclosure is not limited thereto. Any non-substantive modifications made to the present disclosure based on this concept shall be deemed as acts infringing upon the protection scope of the present disclosure.

What is claimed is:

1. A water outlet switching structure, comprising:
an operating member,
a linkage member,
a swinging member,
a switching member,
a first nozzle, and
a second nozzle, wherein:
the operating member is configured to drive the linkage member to move,
the linkage member comprises a first direction-changing surface and a holding surface along a direction of movement of the linkage member,
when the linkage member moves to enable the first direction-changing surface to cooperate with the swinging member, the first direction-changing surface converts the movement of the linkage member into a swing of the swinging member from a first position to a second position,
the swinging member is configured to cooperate with the switching member in a direction-changing manner to convert the swing of the swinging member into movement of the switching member,
during the movement of the switching member, the switching member is configured to enable a water inlet channel to be alternatively in communication with a first water outlet channel or a second water outlet channel to discharge water from the first nozzle or the second nozzle, and
when the linkage member moves to enable the holding surface to cooperate with a first end of the swinging member:
the holding surface maintains the swinging member in the second position,
the water inlet channel is in communication with the second water outlet channel,
the second nozzle discharges the water, and
the operating member is configured to drive the linkage member to move relative to the second nozzle to change a shape of a water outlet port of the second nozzle.

2. The water outlet switching structure according to claim 1, wherein:
the swinging member is a swing rod,
the first end of the swinging member abuts the linkage member, and
a second end of the swinging member abuts the switching member.

3. The water outlet switching structure according to claim 1, wherein:
the switching member comprises a water divider, a switching shaft, and a sealing member arranged on the switching shaft,
the water divider comprises the water inlet channel, the first water outlet channel, and the second water outlet channel,
the switching shaft is located at junctions at which the water inlet channel is in communication with the first water outlet channel and the second water outlet channel, and
during the movement of the switching member, the switching member alternatively closes the junction between the water inlet channel and the first water outlet channel or the junction between the water inlet channel and the second water outlet channel through the sealing member.

4. The water outlet switching structure according to claim 3, wherein:
the switching shaft abuts the water divider through a return spring, and
when the switching shaft moves to enable the second water outlet channel to be in communication with the water inlet channel, the return spring accumulates an elastic return force.

5. The water outlet switching structure according to claim 1, wherein:
the linkage member further comprises a second direction-changing surface, and
when the linkage member moves to enable the holding surface to cooperate with the first end of the swinging member, the second direction-changing surface is operatively coupled to the second nozzle to change the shape of the water outlet port of the second nozzle.

6. The water outlet switching structure according to claim 5, wherein:
the second nozzle further comprises a direction-changing cooperating member, and
the second direction-changing surface is configured to move relative to the second nozzle to convert movement of the second direction-changing surface along an axial direction of the linkage member into movement of the direction-changing cooperating member along a radial direction of the second nozzle.

7. The water outlet switching structure according to claim 6, wherein:
the second direction-changing surface is an inclined surface.

8. The water outlet switching structure according to claim 6, wherein:
the second nozzle further comprises a nozzle body,
the direction-changing cooperating member comprises two clamping plates arranged on two sides of the nozzle body,
the two clamping plates are connected by an elastic member to form a cavity,
a water outlet end of the nozzle body is arranged within the cavity, and
the water outlet end of the nozzle body is operatively coupled to the two clamping plates through a pin shaft.

9. The water outlet switching structure according to claim 8, wherein:
the linkage member is partially arranged between the two clamping plates, and
while the linkage member moves relative to the second nozzle, the second direction-changing surface abuts and cooperates with the two clamping plates to be configured to drive the two clamping plates to splay away from each other.

10. The water outlet switching structure according to claim 8, wherein:
the nozzle body has a linear water outlet port when the two clamping plates are in an initial position.

11. The water outlet switching structure according to claim 1, wherein:
the operating member configured to drive the linkage member to move along an axial direction of the linkage member.

12. The water outlet switching structure according to claim 1, wherein:
the first direction-changing surface is an inclined surface, and
the holding surface is a flat, straight surface connected to an end of the inclined surface and extends along an axial direction of the linkage member.

13. A water outlet switching structure, comprising:
an operating member,
a linkage member, and
a nozzle, wherein:
the linkage member comprises a direction-changing surface, and
the direction-changing surface is configured to be operatively coupled to the nozzle, so that the operating member is configured to drive the linkage member to move relative to the nozzle to change a shape of a water outlet port of the nozzle.

14. The water outlet switching structure according to claim 13, wherein:
the nozzle further comprises a direction-changing cooperating member, and
the direction-changing surface is configured to move relative to the nozzle to convert movement of the direction-changing surface along an axial direction of the linkage member into movement of the direction-changing cooperating member along a radial direction of the nozzle.

15. The water outlet switching structure according to claim 14, wherein:
the direction-changing surface is an inclined surface.

16. The water outlet switching structure according to claim 14, wherein:
the nozzle further comprises a nozzle body,
the direction-changing cooperating member is two clamping plates arranged on two sides of the nozzle body,
the two clamping plates are connected by an elastic member to form a cavity,
a water outlet end of the nozzle body is arranged within the cavity, and
the water outlet end of the nozzle body is operatively coupled to the two clamping plates through a pin shaft.

17. The water outlet switching structure according to claim 16, wherein:
the linkage member is partially arranged between the two clamping plates, and
while the linkage member moves relative to the nozzle, the direction-changing surface abuts and cooperates with the two clamping plates to be configured to drive the two clamping plates to splay away from each other.

18. The water outlet switching structure according to claim 16, wherein:
the nozzle body has a linear water outlet port when the two clamping plates are in an initial position, and
a side of the nozzle body has a clearance notch in communication with the linear water outlet port.

19. The water outlet switching structure according to claim 13, wherein:
the operating member is configured to drive the linkage member to move along an axial direction of the linkage member.

20. A water outlet device, assembled with the water outlet switching structure according to claim 1, comprising:
a body, and
a water outlet cover, wherein:
the body comprises a head portion and a handle,
the first nozzle is arranged on the water outlet cover, and
the second nozzle is arranged at an end of the head portion away from the handle.
